(19) United States
(12) Patent Application Publication
(10) Pub. No.: US 2012/0104522 A1
(43) Pub. Date: May 3, 2012

(54) MAGNETIC TUNNEL JUNCTION CELLS HAVING PERPENDICULAR ANISOTROPY AND ENHANCEMENT LAYER

(75) Inventors: Wonjoon Jung, Bloomington, MN (US); Yuankai Zheng, Freemont, CA (US); Zheng Gao, San Jose, CA (US)

(73) Assignee: SEAGATE TECHNOLOGY LLC, Scotts Valley, CA (US)

(21) Appl. No.: 12/916,738

(22) Filed: Nov. 1, 2010

(51) Int. Cl. H01L 29/82

(52) U.S. Cl. 257/421; 257/E29.323

(57) ABSTRACT

A magnetic tunnel junction cell that includes a ferromagnetic free layer; an enhancement layer having a thickness of at least about 15 Å; an oxide barrier layer; and a ferromagnetic reference layer, wherein the enhancement layer and the oxide barrier layer are positioned between the ferromagnetic reference layer and ferromagnetic free layer and the oxide barrier layer is positioned adjacent the ferromagnetic reference layer, and wherein the ferromagnetic free layer, the ferromagnetic reference layer, and the enhancement layer all have magnetization orientations that are out-of-plane

### BACKGROUND

New types of memory have demonstrated significant potential to compete with commonly utilized forms of memory. For example, non-volatile spin-transfer torque random access memory (referred to herein as ST-RAM) has been discussed as a “universal” memory. Magnetic tunnel junction (MTJ) cells have has attracted much attention for their application in ST-RAM due to their high speed, relatively high density and low power consumption.

Most activities have been focused on MTJ cells with in-plane magnetic anisotropies. However, there are limits on how low the switching current can be for adequate thermal stability, which further limits the size of the CMOS transistor which ultimately limits the density of the memory array. In addition, there is very low tolerance of the cell shape and edge roughness, which can be challenging photolithographic techniques. Techniques, designs and modifications designed to improve magnetic tunnel junction cell structures and materials remain an important area of advancement to maximize the advantages of ST-RAM.

### BRIEF SUMMARY

The present disclosure relates to magnetic spin-torque memory cells, often referred to as magnetic tunnel junction cells, which have magnetic anisotropies (i.e., magnetization orientation) of the associated ferromagnetic layers aligned perpendicular to the wafer plane, or “out-of-plane”.

One particular embodiment of this disclosure is a magnetic tunnel junction cell that includes a ferromagnetic free layer; an enhancement layer having a thickness of at least about 15 Å; an oxide barrier layer; and a ferromagnetic reference layer, wherein the enhancement layer and the oxide barrier layer are positioned between the ferromagnetic reference layer and ferromagnetic free layer and the oxide barrier layer is positioned adjacent the ferromagnetic reference layer, and wherein the ferromagnetic free layer, the ferromagnetic reference layer, and the enhancement layer all have magnetization orientations that are out-of-plane.

Another particular embodiment of this disclosure is a device that includes: a magnetic tunnel junction cell that includes a ferromagnetic free layer; an enhancement layer having a thickness of at least about 15 Å; an oxide barrier layer; and a ferromagnetic reference layer, wherein the enhancement layer and the oxide barrier layer are positioned between the ferromagnetic reference layer and ferromagnetic free layer and the oxide barrier layer is positioned adjacent the ferromagnetic reference layer, and wherein the ferromagnetic free layer, the ferromagnetic reference layer, and the enhancement layer all have magnetization orientations that are out-of-plane; and a transistor, wherein the transistor is electrically connected to the magnetic tunnel junction cell.

Yet another particular embodiment of this disclosure is a memory array that includes a plurality of parallel conductive bit lines; a plurality of parallel conductive word lines that are generally orthogonal to the bit lines; and a plurality of magnetic tunnel junction cells, each magnetic tunnel junction cell including a ferromagnetic free layer; an enhancement layer having a thickness of at least about 15 Å; an oxide barrier layer; and a ferromagnetic reference layer, wherein the enhancement layer and the oxide barrier layer are positioned between the ferromagnetic reference layer and ferromagnetic free layer and the oxide barrier layer is positioned adjacent the ferromagnetic reference layer, and wherein the ferromagnetic free layer, the ferromagnetic reference layer, and the enhancement layer all have magnetization orientations that are out-of-plane, wherein each of the plurality of magnetic tunnel junction cells are disposed at intersections of the bit lines and word lines.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1A is a schematic diagram of an illustrative MTJ cell; FIG. 1B is a schematic diagram of an illustrative MTJ cell that includes an optional pinning layer; FIG. 1C is a schematic diagram of an illustrative MTJ cell that includes an optional enhancement layer and first and second electrodes; FIG. 1D is a schematic diagram of an illustrative MTJ cell with out-of-plane magnetization orientation in a low resistance state; and FIG. 1E is schematic side view diagram of the illustrative magnetic tunnel junction memory cell in a high resistance state;

FIG. 2 is a schematic diagram of an illustrative memory unit including a memory cell and a semiconductor transistor;

FIG. 3 is a schematic diagram of an illustrative memory array;

FIGS. 4A (10 Å CoFeB enhancement layer) and 4B (20 Å CoFeB enhancement layer) are graphs of the perpendicular magnetic moment versus applied magnetic field for a MTJ cell having a 10 Å CoFeB enhancement layer (FIG. 4A) and a 20 Å CoFeB enhancement layer (FIG. 4B).

FIG. 5 shows the TMR ratio and switching current (A/cm²) for an MTJ cell having a 20 ÅCoFeB enhancement layer.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

The present disclosure is directed to various embodiments of magnetic tunnel junction (MTJ) cells having magnetic anisotropies that result in the magnetization orientation of the associated ferromagnetic layers to be aligned perpendicular to the wafer plane, or “out-of-plane”.

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. Any definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

While the present disclosure is not so limited, an appreciation of various aspects of the disclosure will be gained through a discussion of the examples provided below.

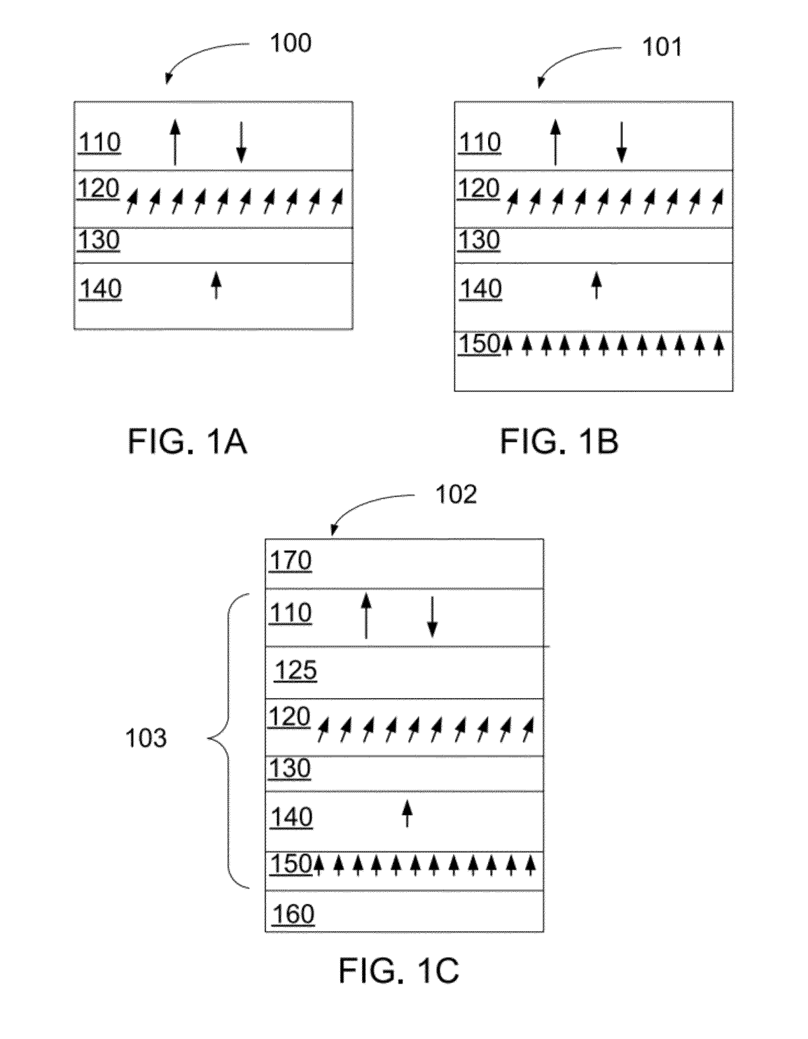

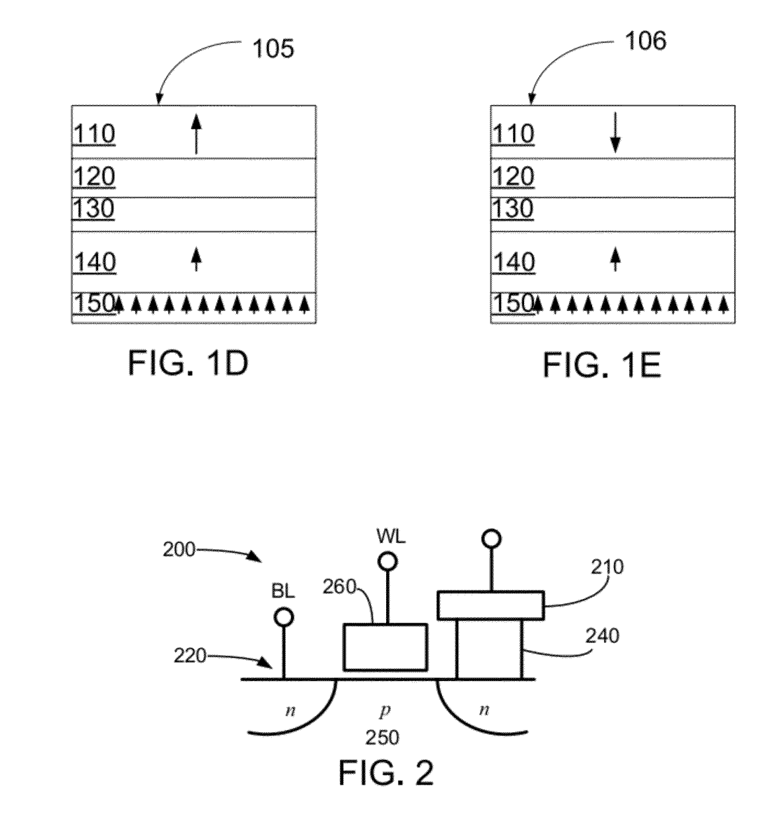

FIG. 1A illustrates an exemplary MTJ cell having perpendicular or out-of-plane magnetic orientation. MTJ cell 100 includes a relatively soft ferromagnetic free layer 110, a ferromagnetic reference (e.g., fixed) layer 140. Ferromagnetic free layer 110 and ferromagnetic reference layer 140 are separated by an oxide barrier layer 130 or non-magnetic tunnel barrier. The MTJ cell 100 also includes an enhancement layer 120. The enhancement layer 120 can be positioned adjacent the oxide barrier layer 130, adjacent the free layer 110 or adjacent both the oxide barrier layer 130 and the free layer 110. The MTJ cell 100 can also be described as the enhancement layer and the oxide barrier layer being positioned between the ferromagnetic reference layer and ferromagnetic free layer; and the oxide barrier layer being positioned adjacent the ferromagnetic reference layer.

Free layer 110, reference layer 140, and enhancement layer 120 each have an associated magnetization orientation. The magnetization orientations of layers 110, 120, and 140 are oriented non-parallel to the layer extension and to the plane of the wafer substrate on which memory cell 100 is formed. In some embodiments, the magnetization orientations of layers 110, 120, and 140 can be referred to as “out-of-plane”. In some embodiments, the magnetization orientations of layers 110, 120, and 140 can be “at least substantially perpendicular”. In some embodiments, the magnetization orientations of layers 110, 120, and 140 can be “perpendicular”. In some embodiments, the magnetization orientations of layers 110 and 140 can be “perpendicular” and the magnetization orientation of layer 120 can be “out-of plane” or “at least substantially perpendicular”. The magnetization orientation of free layer 110 is more readily switchable than the magnetization orientation of both reference layer 140 and enhancement layer 120. Other optional layers, such as seed or capping layers, are not depicted in these figures for clarity.

Free layer 110 and reference layer 140 may independently be made of any useful ferromagnetic (FM) material such as, for example, Fe, Co or Ni and alloys thereof, such as NiFe and CoFe. Either or both of free layer 110 and reference layer 140 may be either a single layer or multilayers. Specific examples of materials that can make up the free layer and the fixed layer can include single layers with perpendicular anisotropy such as TbCoFe, GdCoFe, and FePt; laminated layers such as Co/Pt Co/Ni multilayers; and perpendicular anisotropy materials laminated with high spin polarization ferromagnetic materials such as Co/Fe and CoFeB alloys.

In embodiments, the composition of the material making up at least the free layer 110 (and in embodiments also the reference layer 140) can be chosen to enhance compensation temperatures, perpendicular anisotropy and the exchange coupling with the adjacent enhancement layer. An exemplary composition of FePt that can be utilized for at least the free layer can have an iron (Fe) content that ranges from 35 to 60 atomic percent; and a platinum (Pt) content that ranges from 40 to 65 atomic percent. An exemplary composition of TbCoFe that can be utilized for at least the free layer can have a terbium (Tb) content that ranges from 20 to 35 atomic percent; an iron (Fe) content that ranges from 40 to 75 atomic percent; and a cobalt (Co) content that ranges from 5 to 40 atomic percent.

Free layer 110 and reference layer 140 can generally have thicknesses of at least 20 Å. In embodiments, free layer 110 and reference layer 140 can have thicknesses of at least 50 Å. In embodiments, free layer 110 and reference layer 140 can have thicknesses of 80 Å. In embodiments, free layer 110 and reference layer 140 can have a thickness of 80 Å and be made of TbCoFe for example.

Barrier layer 130 may be made of an electrically insulating material such as, for example an oxide material (e.g., Al₂O₃, TiOₓ or MgOₓ) or a semiconductor material. Barrier layer 130 can be a single layer or can be a layer laminated with another oxide or metal (for example a Mg/MgO bilayer). Barrier layer 130 could optionally be patterned with free layer 110 or with reference layer 140, depending on process feasibility and device reliability.

The enhancement layer 120 can be positioned proximate the free layer 110. In embodiments, the enhancement layer 120 can be positioned directly adjacent to the free layer 110. The enhancement layer 120 can function to enhance the spin polarization of the free layer, which can lead to higher tunneling magnetoresistance (TMR). Disclosed enhancement layers 120 can be slightly decoupled from the free layer 110. This can be accomplished by the enhancement layer 120 being relatively thick, having a slightly canted magnetic moment (relative to the free layer 110), or a combination thereof. The slightly canted magnetic moment of the enhancement layer 120 relative to the free layer 110 can also be characterized as only substantially perpendicular to the wafer substrate.

In embodiments, the enhancement layer 120 can be relatively thick. In embodiments, the enhancement layer 120 can be at least 15 Angstroms (Å) thick. In embodiments, the enhancement layer 120 can be at least 20 Å thick. In embodiments, the enhancement layer 120 can be from 15 Å to 25 Å thick. In embodiments, the enhancement layer can be from 18 Å to 22 Å thick. The thickness of the enhancement layer 120, i.e. at least 15 Å thick, can weaken the exchange coupling between the free layer 110 and the enhancement layer 120, which causes the magnetic moment of the enhancement layer to be canted somewhat. This effect of the thickness of the enhancement layer can be seen in the schematic depiction in FIG. 1A by the arrows which indicate that the magnetic moment of the enhancement layer 120 being slightly off axis from the magnetic moment of the free layer 110. A canted magnetic moment in the enhancement layer can allow the enhancement layer to still increase the TMR but simultaneously decrease the switching current.

The enhancement layer 120 can generally be made of any ferromagnetic materials. In embodiments, the enhancement layer 120 can be made of a ferromagnetic material that has a high spin polarization. For example, the enhancement layer 120 can be made of Fe, Co or Ni and alloys thereof, such as NiFe, CoFe, or CoFeB alloys for example. In embodiments, the enhancement layer 120 can be a CoFeB alloy having a Co composition from 20 to 86 atomic percent, an Fe composition from 10 to 60 percent, and a B composition from 4 to 20 percent. In an embodiment, the enhancement layer 120 is made of CoFeB and has a thickness of 15 Å to 25 Å.

The enhancement layer 120 can also optionally have any thickness but can be formed with a magnetic moment that is slightly off the perpendicular axis of the free layer. This is schematically shown in FIG. 1A. In such an embodiment, it is not necessarily an effect of the enhancement layer, but also the magnetic moment of the enhancement layer itself that can enable more efficient spin torque transfer, which can lead to switching current reduction.

FIG. 1B illustrates another exemplary embodiment of a MTJ cell. This MTJ cell 101 includes an optional pinning layer 150 disposed proximate, or adjacent to the reference layer 140. The pinning layer 150, if present pins the magnetization orientation of reference layer 140. In some embodiments, such a pinning layer 150 may have a zero magnetization, but still can pin the reference layer 140 magnetization. A pinning layer, if present, may be an antiferromagnetically ordered material (AFM) such as PtMn, IrMn, and others.

FIG. 1C shows an exemplary stack or device 102 that includes a MTJ cell 103 as disclosed above. Such a device 102 includes a first electrode 170 that is in electrical contact with ferromagnetic free layer 110 and a second electrode 160 that is in electrical contact with ferromagnetic reference layer 140 or in this particular embodiment pinning layer 150. Electrodes 160, 170 electrically connect ferromagnetic free and reference layers 110, 140 to a control circuit providing read and write currents through layers 110, 140. The resistance across the MTJ cell 103 is determined by the relative orientation of the magnetization vectors or magnetization orientations of ferromagnetic layers 110, 140. In the illustrated embodiment, the magnetization orientation of ferromagnetic reference layer 140 is pinned in a predetermined direction by pinning layer 150 while the magnetization direction of ferromagnetic free layer 110 is free to rotate under the influence of spin torque.

In embodiments, such as that depicted in FIG. 1C, the free layer 110 and the enhancement layer 120 can be separated by an optional insertion layer 125. The optional insertion layer 125 can function to improve the barrier quality, reduce interlayer coupling and improve corrosion resistance in order to achieve a high magnetoresistive ratio. The insertion layer can be made of metallic, semiconductor or insulative materials. Exemplary materials can include for example tantalum (Ta), ruthenium (Ru), chromium (Cr), or magnesium oxide (MgO).

FIG. 1D shows the magnetic tunnel junction memory cell 105 is in the low resistance state where the magnetization orientation of free layer 110 is in the same direction as the magnetization orientation of reference layer 140. In FIG. 1E, magnetic tunnel junction cell 106 is in the high resistance state where the magnetization orientation of free layer 110 is in the opposite direction of the magnetization orientation of reference layer 140. In some embodiments, the low resistance state may be the “0” data state and the high resistance state the “1” data state, whereas in other embodiments, the low resistance state may be “1” and the high resistance state “0”.

Switching the resistance state and hence the data state of magnetic tunnel junction memory cell 105 via spin-transfer occurs when a current, passing through a magnetic layer of magnetic tunnel junction memory cell 105, becomes spin polarized and imparts a spin torque on free layer 110. When a sufficient spin torque is applied to free layer 110, the magnetization orientation of free layer 110 can be switched between two opposite directions and accordingly, magnetic tunnel junction memory cell 105 can be switched between the low resistance state and the high resistance state.

FIG. 2 is a schematic diagram of an illustrative memory unit 200 including a memory element 210 electrically connected to a transistor 220, such as a semiconductor based transistor, via an electrically conducting element 240. Memory element 210 may be any of the MTJ cells described herein. Transistor 220 includes a semiconductor substrate 250 having doped regions (e.g., illustrated as n-doped regions) and a channel region (e.g., illustrated as a p-doped channel region) between the doped regions. Transistor 220 includes a gate 260 that is electrically coupled to a word line WL to allow selection and current to flow from a bit line BL to memory element 210. An array of programmable metallization memory units 200 can be formed on a semiconductor substrate utilizing semiconductor fabrication techniques.

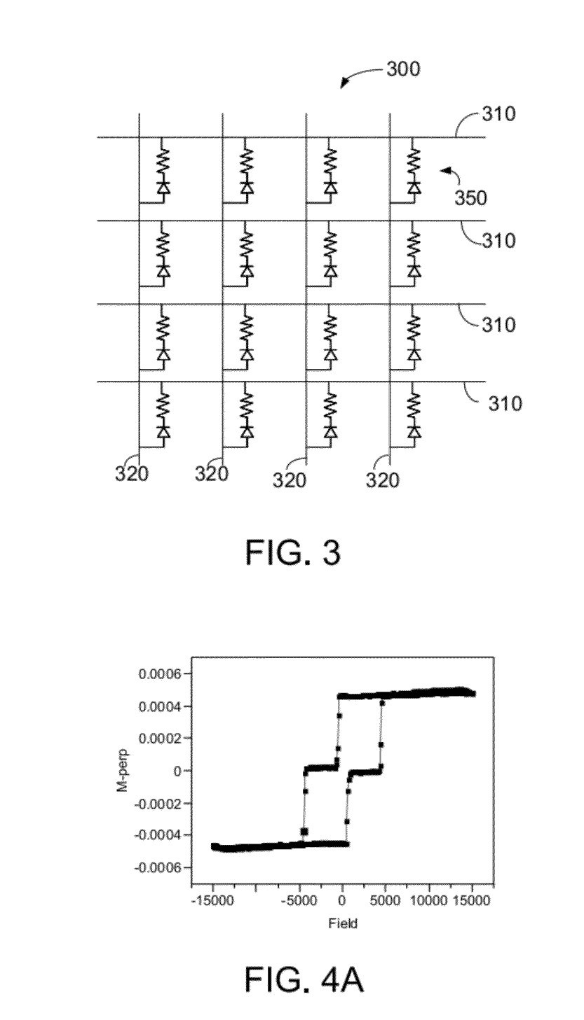

FIG. 3 is a schematic circuit diagram of an illustrative memory array 300. A plurality of memory units 350, described herein can be arranged in an array to form the memory array 300. The memory array 300 includes a number of parallel conductive bit lines 310. The memory array 300 includes a number of parallel conductive word lines 320 that are generally orthogonal to the bit lines 310. The word lines 320 and bit lines 310 form a cross-point array where a memory unit 350 is disposed at each cross-point. The memory unit 350 and memory array 300 can be formed using conventional semiconductor fabrication techniques.

MTJ cells as disclosed herein can be manufactured using various techniques, including for example plasma vapor deposition (PVD), evaporation, and molecular beam epitaxy (MBE).

MTJ cells as disclosed herein can be used in MRAM applications, recording heads, and any applications that utilize large MR ratios while still needing thermal stability and ease of manufacturability. Examples of such diverse applications can include for example sensor applications and oscillator applications.

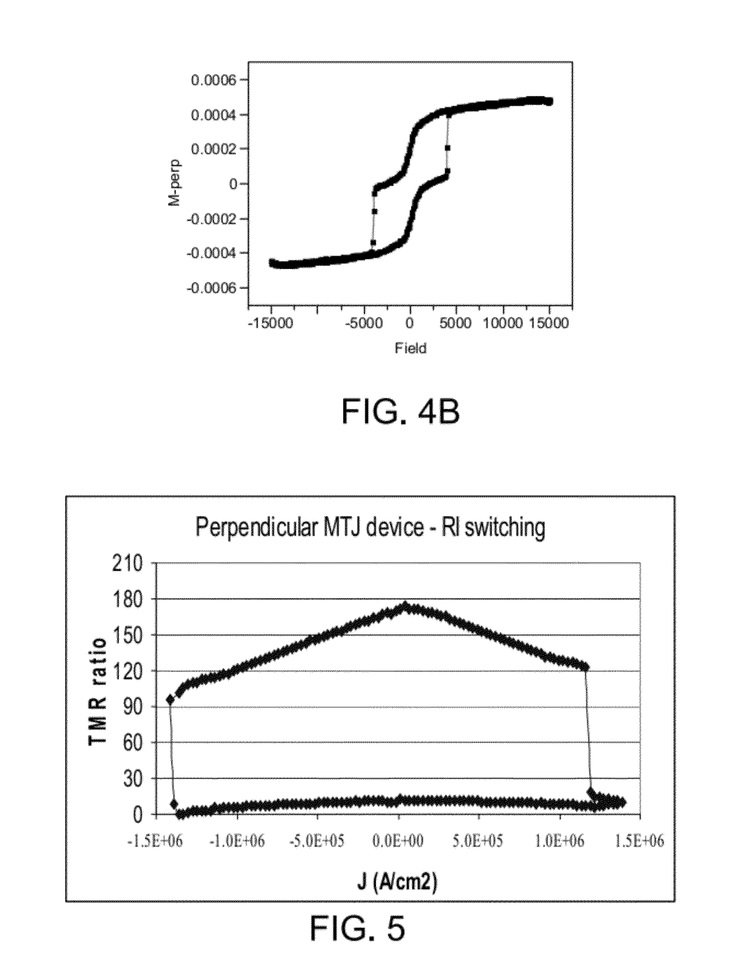

The perpendicular magnetic moment of a MTJ cell having a 80 Å TbCoFe layer and a 10 ÅCoFeB enhancement layer and a MTJ cell having a 80 Å TbCoFe layer and a 20 Å CoFeB enhancement layer as a function of applied magnetic field were compared. The results can be seen in FIGS. 4A (10 Å CoFeB enhancement layer) and 4B (20 Å CoFeB enhancement layer). As shown by the smoother transitions, the coupling of the enhancement layer to the free layer is not as strong in the MTJ cell having the 20 Å CoFeB enhancement layer. FIG. 4C shows the TMR ratio and switching current (A/cm²) for the MTJ cell having the 20 Å CoFeB enhancement layer. As seen from FIG. 5, the MTC cell having the 20 Å CoFeB enhancement layer achieved a MR ratio of 160% with a RA product of 35 Ω/μm². When such an MTJ cell would be used in a MRAM application, the critical switching current could be as low as 1.5×10⁶ A/cm², which can be very beneficial to provide a lower energy consumption memory.

In this disclosure, various structural designs of magnetic tunnel junction cells with perpendicular magnetic anisotropies are provided. The designs and patterning processes allow reduced switching current with adequate thermal stability, and enable high area density with increased tolerance to process variations.

Thus, embodiments of MAGNETIC TUNNEL JUNCTION CELLS HAVING PERPENDICULAR ANISOTROPY AND ENHANCEMENT LAYER are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present disclosure is limited only by the claims that follow.

What is claimed is:

1. A magnetic tunnel junction cell comprising:
a ferromagnetic free layer;
an enhancement layer having a thickness of at least about 15 Å;
an oxide barrier layer; and
a ferromagnetic reference layer,
wherein the enhancement layer and the oxide barrier layer are positioned between the ferromagnetic reference layer and ferromagnetic free layer and the oxide barrier layer is positioned adjacent the ferromagnetic reference layer, and
wherein the ferromagnetic free layer, the ferromagnetic reference layer, and the enhancement layer all have magnetization orientations that are out-of-plane.

2. The magnetic tunnel junction cell according to claim 1, wherein the enhancement layer is positioned directly adjacent to the ferromagnetic free layer.

3. The magnetic tunnel junction cell according to claim 1, wherein the enhancement layer is slightly decoupled from the ferromagnetic free layer.

4. The magnetic tunnel junction cell according to claim 1, wherein the enhancement layer is at least about 20 Å thick.

5. The magnetic tunnel junction cell according to claim 1, wherein the enhancement layer is from about 15 Å to 20 Åthick.

6. The magnetic tunnel junction cell according to claim 1, wherein the enhancement layer comprises NiFe, CoFe, or CoFeB.

7. The magnetic tunnel junction cell according to claim 1 further comprising a pinning layer directly adjacent the ferromagnetic reference layer.

8. The magnetic tunnel junction cell according to claim 1 further comprising an insertion layer positioned between the ferromagnetic free layer and the enhancement layer.

9. The magnetic tunnel junction cell according to claim 8, wherein the insertion layer comprises tantalum, ruthenium, chromium, or magnesium oxide.

10. The magnetic tunnel junction cell according to claim 1, wherein the ferromagnetic free layer and the ferromagnetic reference layer are chosen from:
single layers of TbCoFe, GdCoFe, or FePt; and
laminated layers of Co/PtCo/Ni.

11. The magnetic tunnel junction cell according to claim 10, wherein the ferromagnetic free layer and the ferromagnetic reference layer both comprise FePt having an iron (Fe) content of from about 35 to about 60 atomic percent.

12. The magnetic tunnel junction cell according to claim 10, wherein the ferromagnetic free layer and the ferromagnetic reference layer both comprise TbCoFe with a terbium (Tb) content from about 20 to about 35 atomic percent and an iron (Fe) content from about 40 to about 75 atomic percent.

13. A device comprising:
a magnetic tunnel junction cell comprising:
a ferromagnetic free layer;
an enhancement layer having a thickness of at least about 15 Å;
an oxide barrier layer; and
a ferromagnetic reference layer,
wherein the enhancement layer and the oxide barrier layer are positioned between the ferromagnetic reference layer and ferromagnetic free layer and the oxide barrier layer is positioned adjacent the ferromagnetic reference layer, and
wherein the ferromagnetic free layer, the ferromagnetic reference layer, and the enhancement layer all have magnetization orientations that are out-of-plane; and
a transistor,
wherein the transistor is electrically connected to the magnetic tunnel junction cell.

14. The device according to claim 13, wherein the enhancement layer is positioned directly adjacent to the ferromagnetic free layer.

15. The device according to claim 13, wherein the enhancement layer is at least about 20 Å thick.

16. The device according to claim 13, wherein the enhancement layer is from about 15 Å to 20 Åthick.

17. The device according to claim 13, wherein the enhancement layer comprises NiFe, CoFe, or CoFeB.

18. A memory array comprising:
a plurality of parallel conductive bit lines;
a plurality of parallel conductive word lines that are generally orthogonal to the bit lines; and
a plurality of magnetic tunnel junction cells, each magnetic tunnel junction cell comprising:
a ferromagnetic free layer;
an enhancement layer having a thickness of at least about 15 Å;
an oxide barrier layer; and
a ferromagnetic reference layer,
wherein the enhancement layer and the oxide barrier layer are positioned between the ferromagnetic reference layer and ferromagnetic free layer and the oxide barrier layer is positioned adjacent the ferromagnetic reference layer, and
wherein the ferromagnetic free layer, the ferromagnetic reference layer, and the enhancement layer all have magnetization orientations that are out-of-plane,
wherein each of the plurality of magnetic tunnel junction cells are disposed at intersections of the bit lines and word lines.

19. The memory array according to claim 18, wherein the enhancement layer is at least about 20 Å thick.

20. The memory array according to claim 18, wherein the enhancement layer comprises NiFe, CoFe, or CoFeB.
